(19) United States
(12) Patent Application Publication
(10) Pub. No.: US 2014/0060617 A1
(43) Pub. Date: Mar. 6, 2014

(54) SEMICONDUCTOR DEVICE, SOLAR CELL MODULE, SOLAR CELL STRING, AND SOLAR CELL ARRAY

(71) Applicant: FUJIFILM Corporation, Tokyo (JP)

(72) Inventors: Youta MIYASHITA, Ashigarakami-gun (JP); Haruo YAGO, Ashigarakami-gun (JP); Shigenori YUYA, Ashigarakami-gun (JP)

(73) Assignee: FUJIFILM Corporation, Tokyo (JP)

(21) Appl. No.: 14/078,026

(22) Filed: Nov. 12, 2013

Related U.S. Application Data
(63) Continuation of application No. PCT/JP2012/061547, filed on May 1, 2012.

(30) Foreign Application Priority Data
May 13, 2011 (JP) 2011-107995

(51) Int. Cl. H01L 31/05; H01L 23/528

(52) U.S. Cl. CPC H01L 31/0504; H01L 23/528
USPC 136/244; 257/786

(57) ABSTRACT

The semiconductor device has a conductive substrate formed from a conductive material, a nonconductive layer provided on at least part of the surface of the conductive substrate, plural semiconductor elements provided on this nonconductive layer, wiring that electrically connects the plural semiconductor elements, and at least one electrical connection part between the nonconductive layer and semiconductor elements or wiring. The semiconductor element for which the potential difference with the conductive substrate is the greatest is disposed in a position other than the geometric terminal of the arrangement created by the plural semiconductor elements.

### BACKGROUND OF THE INVENTION

The present invention relates to a semiconductor device, a solar cell module, a solar cell string, and a solar cell array. Particularly, the present invention relates to a semiconductor element arrangement method for improving insulating properties between a conductive substrate made of a conductive material and semiconductor elements in a semiconductor device, and to a solar cell module, a solar cell string, and a solar cell array using the semiconductor elements.

Substrates made of conductive materials such as metals or alloys that feature lightweight properties and flexibility have possibilities of being applicable for various purposes. Moreover, being able to endure a high-temperature process, the substrate made of the conductive material can also be applied to semiconductors that cannot be handled with a resin substrate such as polyimide. For example, if the substrate is used as a substrate for a solar cell, photoelectric conversion efficiency can be improved, and accordingly, increase in the efficiency of solar cell can be expected.

However, when a conductive material such as metal or alloy is used as a substrate, it is necessary to dispose an insulating layer between semiconductor elements as well as a wiring that are formed on the substrate and the substrate so as to regulate potential differences among the respective portions. Generally, the insulating layer is disposed on at least one surface of the substrate made of the conductive material.

As the insulating layer, oxides obtained by anodizing the substrate materials are used (for example, JP 4612731 B).

As a method for improving insulating properties of the insulating layer, JP 4612731 B discloses a method of equalizing a potential in the vicinity of a middle position of elements that are serially connected (that is, solar cells) with a potential of a substrate made of a conductive material (metal substrate) so as to reduce a potential difference between the elements and the substrate.

### SUMMARY OF THE INVENTION

However, in JP 4612731 B, the potential difference between the elements and the substrate is maximized at terminal portions (both ends) of the array composed of semiconductor elements, and this leads to a problem that due to creeping discharge, an electric field concentration in a corner, and the like, insulating properties deteriorate.

FIGS. 7A and 7B show the results obtained by simulating the state of electric field concentration caused in the electrode corner. FIG. 7A shows the result obtained when a curvature of the corner is varied, and FIG. 7B shows the result obtained when an angle of the corner is varied.

From FIG. 7A, it is understood that an electric field Eₘₐₓ at the end of the electrode having a diameter of 25 mm (corresponding to the corner of an electrode having a radius of curvature of 12.5 mm) is about 1.3 times an electric filed E₀ in the center of the electrode. From FIG. 7B, it is understood that the electric field Eₘₐₓ created when the corner forms a right angle is about 1.1 times the electric field E₀ in the center of the electrode.

In order to inhibit the electric field concentration in the corner, for example, WO 2010/049495 discloses a method of making the corner round, and JP 2007-35695 A discloses a method of making the corner form an obtuse angle. However, even with these methods, the potential difference between the elements and the substrate is still maximized at the terminal portions, there is a problem that the insulating properties are poor in the terminal portions.

Moreover, in order to reduce planar distribution of potential differences between wirings on a substrate, JP 2009-260147 A devises a method of arranging wirings.

However, the method disclosed in JP 2009-260147 A does not disclose a method of regulating potentials between the semiconductor elements as well as wiring and the substrate when the substrate is made of a conductive material. Accordingly, even if this method is used as is, the insulating properties with respect to the substrate cannot be improved.

An object of the present invention is to solve the problems in the above-mentioned conventional technologies, and to provide a semiconductor device, a solar cell module, a solar cell string, and a solar cell array that are excellent in withstand voltage properties in insulation between plural semiconductor elements arranged on a conductive substrate made of a conductive material and the conductive substrate.

In order to achieve the above object, a first aspect of the present invention comprises a conductive substrate that is made of a conductive material, a non-conductive layer that is disposed in at least one portion of the surface of the substrate and made of a non-conductive material, plural semiconductor elements that are arranged on the non-conductive layer, a wiring that electrically connects the plural semiconductor elements to one another, and at least one electrical connection portion that connects the conductive substrate to the semiconductor elements or the wiring, in which semiconductor element showing a maximum potential difference with respect to the conductive substrate is arranged in a position excluding a geometric end of the array composed of the plural semiconductor elements.

In the present invention, for example, when the array composed of the plural semiconductor elements is a line segment as shown in FIG. 1A, a geometric end refers to a semiconductor element 51a that includes a vertex of the line segment among plural semiconductor elements 51. Moreover, when the array composed of the plural semiconductor elements 51 is in the form of a polygon as shown in FIG. 1B, the geometric end refers to the semiconductor element 51a that includes a vertex of the polygon. Further, when the form of the semiconductor element 51 is a polygon as shown in FIG. 1C, the geometric end refers to the semiconductor element 51a that includes a vertex thereof, and when the array of the plural semiconductor elements 51 is in the form of a concentric circle as shown in FIG. 1D, the geometric end refers to the semiconductor element 51a that includes the circumference of the circle. Regardless of the form of one semiconductor element, in the present invention, one of the semiconductor elements 51a described above refers to a geometric end.

In the present invention, the electrical connection portion includes, for example, a mechanical contact portion that is pushed against a portion of a semiconductor element by applying pressure, a junction formed by an alloying such as soldering, a welded portion formed by performing heating and welding on the relevant site, and the like. In addition, even if a substrate does not come into contact with semiconductor elements, portions that can practically determine a potential of the semiconductor elements with respect to the substrate, for example, such as a portion having a thin insulating layer and a portion having semiconductive properties, are included in the electrical connection portion.

By the electrical connection portion, a potential difference between a conductive substrate (conductive material portion) and semiconductor elements is regulated.

If the respective semiconductor elements are connected to each other in series or in parallel by a wiring, the distribution of the potential difference between the conductive substrate and the semiconductor elements or the wiring is regulated.

If a semiconductor element showing the maximum potential difference with respect to the conductive substrate (conductive material portion) is arranged in a position excluding the geometric end of the array, the electric field of the terminal portion is reduced.

If the electric field in the terminal portion is reduced, withstand voltage properties in insulation between the conductive substrate (conductive material portion) and the semiconductor elements is improved.

Moreover, the semiconductor element that comes into contact with the electrical connection portion is preferably arranged within a range that includes 10% of the number of the plural semiconductor elements from at least one terminal of the array, and more preferably arranged within a range that includes 5% of the number of the plural semiconductor elements from at least one terminal of the array. When the plural semiconductor elements are in contact with the electrical connection portions, the semiconductor elements preferably are equipotential with each other. It is particularly preferable that the semiconductor element is characterized by being a semiconductor element arranged in at least one terminal of the array.

If the vicinity of the end of the array becomes equipotential with the conductive material portion, it is possible to reduce the potential difference in the end portion.

If the potential difference in the vicinity of the end is reduced, the electric field concentration is relieved, and the overall insulating properties are improved.

Moreover, a semiconductor device of a second aspect of the present invention is characterized in that the nonconductive layer is formed by subjecting the conductive substrate to anodization treatment, and among plural semiconductor elements, at least one semiconductor element having a maximum potential comes into contact with the electrical connection portion.

It is known that the insulating properties of an anodized film are more improved when the metal as a base thereof is used as a positive electrode. If the semiconductor element having a maximum potential becomes equipotential with the conductive substrate (conductive material portion), the conductive substrate (conductive material portion) always becomes a positive electrode, and accordingly, overall insulating properties are improved.

As the conductive substrate, substrates made of titanium or aluminum having lightweight properties and flexibility are preferable, and substrates made of inexpensive aluminum are more preferable. Further, in order to improve various characteristics, not the substrates made of aluminum but composite aluminum substrates made of composite materials are preferable. The composite materials include, for example, materials as a combination of a resin or other metals with aluminum. Among these, a clad substrate composed of a steel plate or a stainless steel plate and an aluminum plate is more preferable since this substrate can improve thermal resistance of aluminum.

In addition, a semiconductor device of a third aspect of the present invention is characterized in that plural semiconductor elements are arranged in the form of a concentric circle, and at least one semiconductor element showing a maximum potential difference with respect to the conductive substrate is disposed as a center of the concentric circle-like arrangement.

Due to the concentric circle-like array, the electric field concentration is relieved, and a potential difference between at least one semiconductor element that shows a maximum potential difference with respect to the conductive substrate and the conductive substrate is caused in a position farthest away from the end of the array. Accordingly, the electric field in a direction parallel with the conductive substrate decreases, and accordingly, overall insulating properties are improved.

Further, a semiconductor device a fourth aspect of the present invention is characterized in that plural semiconductor elements are arranged in a straight line, and two serially connected arrays of the semiconductor elements connected to each other in parallel. Since all semiconductor elements are arranged in a straight line, the production process does not increase. Moreover, since two series circuits are connected to each other in parallel, an output voltage is reduced by half, and thus a required withstand voltage can be reduced by half. In addition, since a semiconductor element showing a maximum potential difference with respect to the substrate is disposed in a position excluding the geometric end of the array composed of the semiconductor elements, the electric field concentration is reduced, and the insulating properties can be improved. Likewise, by increasing the number of series circuits to be connected to each other in parallel by 4, 8, and so forth, the output voltage can be reduced by one fourth, one eighth, and so forth, and a withstand voltage can be further reduced.

Moreover, in two arrays, a potential difference is maximized between a connection portion of the arrays and semiconductor elements positioned at both ends of all of the arrays. However, since semiconductor element showing a maximum potential difference with respect to the conductive substrate is not arranged in both ends of the arrays, the potential difference with respect to the conductive substrate is maximized in the semiconductor element or wiring positioned in the connection portion of the two arrays. As a result, the insulating properties between the geometric end of the array, in which the electric field concentration easily occurs, and the conductive substrate are improved, whereby overall insulating properties are improved.

According to the present invention, a semiconductor device excellent in withstand voltage properties in insulation between plural semiconductor elements arranged on a conductive substrate and the conductive substrate can be provided. Moreover, according to the present invention, because of the improvement in the withstand voltage properties in insulation, a high-performance device can be produced by increasing the number of semiconductor elements. Further, by decreasing the thickness of the nonconductive layer, the device can be produced at low cost.

In addition, since the insulating properties are improved particularly at the and portion of the device, the insulating properties of the device with respect to the surroundings thereof are also improved. Accordingly, for example, a light and firm conductive frame can be disposed in the surroundings of the device.

Moreover, when plural semiconductor elements are arranged in a straight line, and two serially connected arrays are connected to each other in parallel, the output can be divided into two systems by the parallel circuit. Accordingly, even when half of the device is in failure, half of the output can be maintained. Furthermore, if the number of the parallel circuit is increased, failure probability is further reduced, and durability can be further increased.

Further, due to the improved insulating properties, as the semiconductor device, solar cell modules that are connected to each other in series and produce output at a high voltage are preferable, and thin-film type or integrated type solar cell modules that are required to have lightweight properties and flexibility are more preferable. Particularly, CIGS-based solar cell modules that can yield high efficiency are preferable. Moreover, by using these solar cell modules, solar cell strings and solar cell arrays can be made.

In addition, due to the improved insulating properties, when the same voltage is output, an ineffective area formed in the end portion of the substrate can be reduced. Accordingly, it is possible to efficiently use the material and reduce cost.

### BRIEF DESCRIPTION OF THE DRAWINGS

FIG. 1A is a schematic view illustrating a state where plural semiconductor elements are arranged in a line, FIG. 1B is a schematic view illustrating a state where plural semiconductor elements are arranged in a polygonal shape, FIG. 1C is a schematic view illustrating a state where polygonally-shaped semiconductor elements are arranged, and FIG. 1D is a schematic view illustrating a state where plural semiconductor elements are arranged in the form of a circle.

FIG. 2 is a schematic cross-sectional view of a photoelectric conversion device as a first embodiment of a semiconductor device of the present invention.

FIG. 3 is a configuration diagram of a circuit of the photoelectric conversion device as the first embodiment of the semiconductor device of the present invention.

FIG. 4 is a schematic perspective view that illustrates the photoelectric conversion device under a production process for describing an example of a production step of the photoelectric conversion device as the first embodiment of the semiconductor device of the present invention.

FIG. 5 is a flowchart illustrating an example of a production method of the photoelectric conversion device as the first embodiment of the Present invention.

FIG. 6 is a schematic cross-sectional view of a photoelectric conversion device as a second embodiment of the semiconductor device of the present invention.

FIGS. 7A and B show the results obtained by simulating the state of the electric field concentration in the corner of an electrode. FIG. 7A shows the results obtained when a curvature of the corner is varied, and FIG. 7B shows the results obtained when an angle of the corner is varied.

FIG. 8 is a schematic cross-sectional view illustrating a conventional photoelectric conversion device.

### DETAILED DESCRIPTION OF THE INVENTION

Hereinafter, based on preferable embodiments illustrated in the attached drawings, the semiconductor device of the present invention will be described in detail.

In the present embodiment, as the semiconductor device, a photoelectric conversion device (solar cell module) in which semiconductor elements comprise photoelectric conversion semiconductor elements (photoelectric conversion elements) will be exemplified and described.

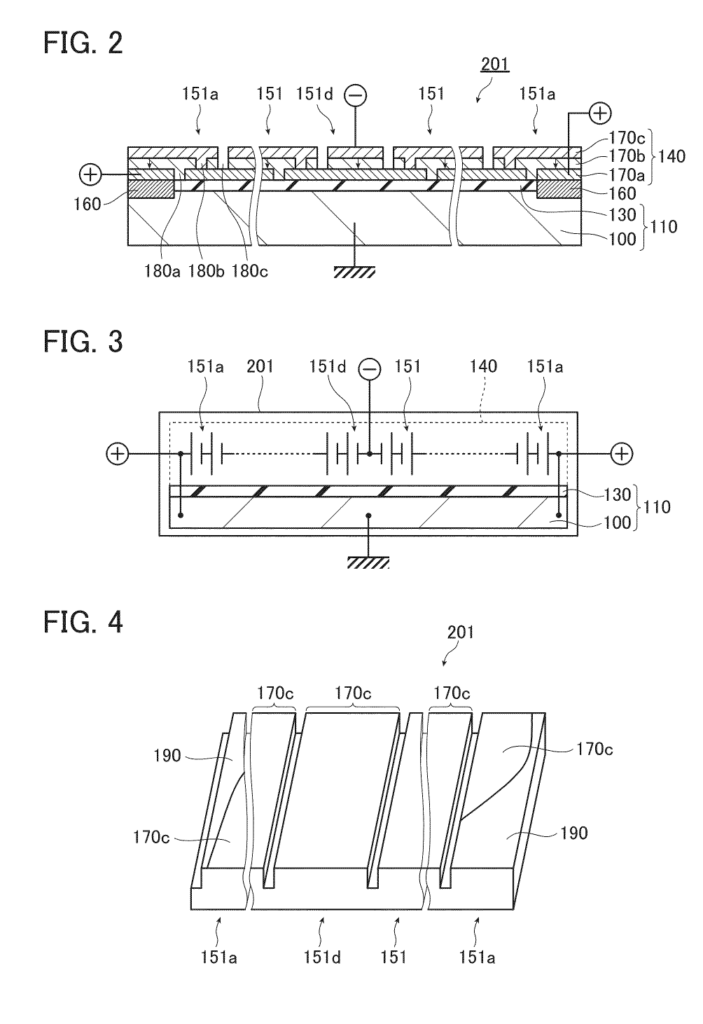

FIG. 2 is a schematic cross-sectional view of a photoelectric conversion device as a first embodiment of the semiconductor device of the present invention, and FIG. 3 is a configuration diagram of a circuit of the photoelectric conversion device as the first embodiment of the semiconductor device of the present invention.

As shown in FIG. 2, a photoelectric conversion device 201 (solar cell module) of the present invention has, for example, a support substrate 110 (a substrate made of a conductive material+a layer made of a nonconductive material) comprising a grounded conductive substrate 100 that has an approximately rectangular shape and is made of a conductive material and a nonconductive layer (insulating layer) 130 that is formed on the conductive substrate 100 and made of a nonconductive material, and a power-generating layer 140 that is formed on the nonconductive layer 130 and made of plural solar cells 151 (photoelectric conversion elements) of the photoelectric conversion device 201.

The power-generating layer 140 has the constitution in which the plural solar cells 151 are arranged in a straight line, and two serially connected arrays are connected to each other in parallel. In FIG. 2, on either side of the negative electrode at the center, each of two serially connected arrays is placed. Therefore, there are two arrays in total, and these two arrays are connected to each other in parallel.

The photoelectric conversion device 201 of the present invention is characterized in that the positive electrode (+) side of at least one solar cell 151a, which is positioned at one end or both ends of the plural solar cells 151 of the power-generating layer 140, is connected as a positive electrode terminal to a positive electrode terminal of an electric contact box not shown in the drawing through a ribbon-like lead wire not shown in the drawing and is electrically connected as a grounding terminal directly to the conductive substrate 100 of the support substrate 110 so as to be grounded, and that a negative electrode (−) side of the solar cell 151 positioned approximately at the center of the plural solar cells 151, that is, one or two solar cells 151d positioned at the center of the plural solar cells 151 are connected as a negative electrode terminal to a negative electrode terminal of the electric contact box not shown in the drawing through a ribbon-like lead wire not shown in the drawing.

In the photoelectric conversion device 201 of the present invention, as shown in FIG. 3, the conductive substrate 100 of the support substrate 110 is grounded, and a solar cell 151a for grounding of which a positive electrode is electrically connected directly to the conductive substrate 100 of the support substrate 110 is grounded through a conductive layer 160. The solar cell 151a for grounding is most preferably a solar cell positioned at either end of the plural solar cells 151.

In the above constitution, a potential difference V1d is maximized between the solar cell 151d at the center of the power-generating layer among all of the solar cells 151 and the conductive substrate 100. Therefore, in the photoelectric conversion device 201, a withstand voltage VW1 required between the power-generating layer 140 and the conductive substrate 100 becomes almost the same as a withstand voltage Vw1d required from the potential difference V1d.

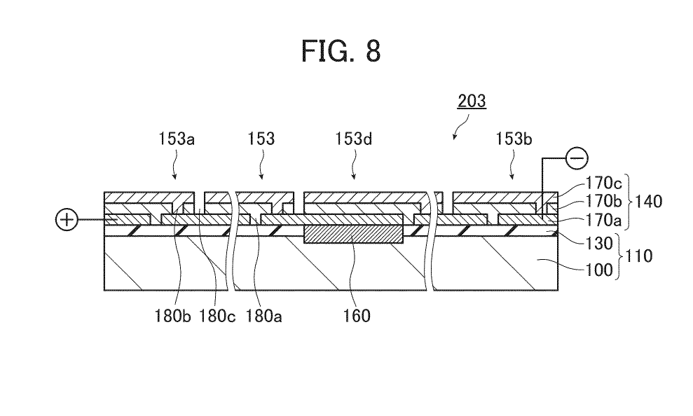

On the other hand, in a conventional photoelectric conversion device 203 which is shown in FIG. 8 as a first embodiment of JP 4612731 B and constituted only with solar cells 153 connected to each other in series, a potential difference V2d between one of the solar cells 153d and the conductive substrate 100 is maximized. Therefore, a withstand voltage VW2 required between the power-generating layer 140 and the conductive substrate 100 becomes approximately the same as a withstand voltage Vw2d required from the potential difference V2d. The photoelectric conversion device 203 corresponds to a solar cell module 10 of JP 4612731 B.

When the number of solar cells in the photoelectric conversion device 201 of the present embodiment is the same as that of the conventional photoelectric conversion device 203, the output of the respective devices becomes almost the same. However, in the periphery of the power-generating layer which is required to have a high withstand voltage due to the influence of the electric field concentration or creeping discharge, only in two sides of the solar cell 151d that face the end of the substrate the potential difference with respect to the conductive substrate 100 becomes maximum and the electric field concentration occurs in the photoelectric conversion device 201 of the present embodiment. In contrast with this, in the conventional photoelectric conversion device 203, over three sides of a solar cell 153a or 153d that face the end of the substrate the potential difference with respect to the conductive substrate 100 becomes maximum and the electric field concentration occurs. Accordingly, the photoelectric conversion device 201 of the present embodiment is advantageous in terms of insulating properties.

Among 4 sides of the cell 153a or 153b, which is at either end of the power-generating layer 140, forming a planar shape, three sides face the end of the substrate, and the remaining one side faces the adjacent cell.

As described above, in the photoelectric conversion device 201 of the present embodiment, the solar cell 151 showing the largest potential difference with respect to the conductive substrate 100 is disposed in a position excluding at least one solar cell positioned at either end or both ends of the plural solar cells 151 of the power-generating layer 140. Therefore, it is possible to reduce the potential difference between the solar cell and the conductive substrate 100 in the periphery of the power-generating layer 140, whereby the insulating properties are improved.

Further, in the photoelectric conversion device 201 shown in FIG. 2, the solar cell 151a for grounding is placed in a position of at least one solar cell positioned at either end or both ends of the plural solar cells 151 of the power-generating layer 140. However, the present invention is not limited thereto, and solar cells in the vicinity of both ends of the power-generating layer 140 may be used as the solar cell 151a for grounding. Moreover, at least one solar cell that is within a range including 10% of the number of the plural solar cells 151 from both ends of the power-generating layer 140 may also be used. The reason is as follows. That is, from the solar cell 151d to at least one solar cell 151a positioned at either end or both ends of the plural solar cells 151 of one power-generating layer 140, the solar cells 151 are connected to each other in series, and the number of the solar cells 151 from the solar cell 151d to one solar cell in the vicinity of either end accounts for 40% or more of the total solar cell number. Accordingly, the potential difference V1d becomes not less than four times as large as a potential difference V1c between the solar cell in the vicinity of either end of the power-generating layer 140 and the conductive substrate 100. Consequently, in the photoelectric conversion device 201, even if the solar cell 151a for grounding is placed in the position of the solar cell in the vicinity of either end, the potential difference V1d is maximized among all of the solar cells 151, just like the case described above.

Moreover, if the solar cell 151a for grounding is placed in the position of at least one solar cell that is within a range including 5% of the number of the plural solar cells 151 from either end of the power-generating layer 140, the potential difference V1d becomes not less than nine times as large as Va1. Accordingly, this is more preferable than using at least one solar cell that is within a range including 10% of the number of the plural solar cells 151 from either end.

The support substrate 110 used in the photoelectric conversion device 201 illustrated as an example in the drawing is a metal plate with an insulating layer that has the conductive substrate 100 and the nonconductive layer 130 formed thereon. The support substrate 110 is not particularly limited as long as it is a metal plate with an insulating layer. However, it is preferable that the support substrate 110 be obtained by anodizing at least one surface of an aluminum (Al) plate to form the anodized film as the nonconductive layer 130 and using the other surface of the Al plate that has not been anodized as the conductive substrate 100.

Herein, the conductive substrate 100 is not particularly limited as long as it makes it possible to form the nonconductive layer 130 and can support the power-generating layer 140 when the conductive substrate 100 is used for the support substrate 110 which is a metal plate with an insulating layer. As the conductive substrate 100, an Al substrate in which at least one surface thereof is an Al layer is preferable, and examples thereof include an Al substrate, a composite Al substrate made of composite materials comprising Al and other metals, and the like.

When the support substrate 110 which is a metal plate with an insulating layer is produced, a thickness thereof is preferably 0.05 mm to 10 mm. When the support substrate 110 is produced from an Al substrate, a composite Al substrate, or the like, it is necessary to set the thickness thereof by foreseeing the decrease of thickness in anodization, as well as in pre-washing and polishing of anodization in advance.

In the present invention, as the Al substrate, for example, 1000-series pure Al plates of the Japanese Industrial Standards (JIS), or Al alloy plats, for example, alloy plates composed of Al and other metal elements, such as Al—Mn-based alloy plates, Al—Mg-based alloy plates, Al—Mn-Mg-based alloy plates, Al—Zr-based alloy plates, Al—Si-based alloy plates, and Al—Mg—Si-based alloy plates, may be used.

Moreover, as the composite Al substrate, clad plates composed of an Al plate and other metal plates, for example, such as clad plates composed of an Al plate and a stainless steel (SUS) plate and clad plates obtained by interposing various steel plates between two Al plates may be used. In the present invention, as other metal plates constituting the clad plates together with the Al plate, various stainless steel plates and other plate materials made of steel such as mild steel, 42 Invar alloy, Kovar alloy, or 36 Invar alloy may be used. Furthermore, metal plates usable as roofing materials or wall materials of houses or buildings may be used such that the photoelectric conversion device of the present invention can be used as a solar cell panel integrated into roofing material.

The Al plate or Al alloy plate used herein may contain various trace metallic elements such as Fe, Si, Mn, Cu, Mg, Cr, Zn, Bi, Ni, and Ti.

The nonconductive layer 130 formed on the conductive substrate 100 is not particularly limited. When the conductive substrate 100 is an Al substrate or a composite Al substrate, it is preferable that the Al substrate or the composite Al substrate be anodized to form the nonconductive layer 130 as an anodized film formed on the surface thereof. The Al substrate or the composite Al substrate can be anodized in a manner in which the Al substrate or the composite Al substrate is used as an anode, soaked into an electrolyte solution together with a cathode, and subjected to electrolytic treatment by application of a voltage between the anode and cathode.

In addition, the anodized film to be the nonconductive layer 130 may be formed on one surface of the Al layer of the Al substrate or the composite Al substrate to be the conductive substrate 100. However, in the case of an Al substrate or a clad plate interposed between two Al plates, it is preferable to dispose an anodized film on both surfaces of the Al layer so as to suppress warps caused by the difference in a thermal expansion coefficient between the Al layer and the anodized film or cracks and the like caused in the anodized film in the step of forming the power-generating layer 140 or the like.

Further, the thickness of the nonconductive layer 130 formed in this manner, that is, the thickness of the anodized film is not particularly limited. The nonconductive layer 130 just needs to have insulating properties and surface hardness for preventing damage and the like caused by mechanical impact at the time of handling, but if the nonconductive layer 130 is excessively thick, sometimes problems arise in view of flexibility. Therefore, the thickness of the nonconductive layer 130 is preferably 0.5 μm to 50 μm. The thickness of the nonconductive layer 130 can be controlled by constant-current electrolysis or constant-voltage electrolysis and by a period of time of electrolysis.

In addition, the type of the nonconductive layer 130 may be various oxide layers of glass and the like that contain elements such as Si, Ca, Zn, B, P, and Ti and formed by various methods such as vapor deposition and a sol-gel method, in addition to the anodized film of Al.

The photoelectric conversion device 201 as the first embodiment of the present invention shown in FIG. 2 is called a substrate type, and the power-generating layer 140 disposed in the photoelectric conversion device 201 is a thin-film integrated type. The power-generating layer 140 has the solar cells 151a for grounding arranged at both ends of the power-generating layer 140 on the nonconductive layer 130 of the support substrate 110, and plural solar cells 151 which are arranged in a straight line while being adjacent to the solar cells 151a for grounding and formed by connecting two serially connected arrays to each other in parallel.

The solar cell 151 has a back electrode 170a that is formed on the surface of the nonconductive layer 130 of the support substrate 110 of FIG. 2, a photoelectric conversion layer 170b that is formed on the back electrode 170a and converts received light into electricity, and a transparent electrode 170c that is formed on the photoelectric conversion layer 170b. The back electrode 170a, the photoelectric conversion layer 170b, and the transparent electrode 170c are laminated in this order on the nonconductive layer 130 to form the solar cell 151.

Meanwhile, the solar cell 151a for grounding is a portion which is a feature of the present invention, and in this cell, a part of the nonconductive layer 130 formed on the support substrate 110 of the solar cell 151 becomes a conductive layer 160. Just like the solar cell 151, the back electrode 170a, the photoelectric conversion layer 170b, and the transparent electrode 170c are laminated in this order on the conductive layer 160 to form the solar cell 151a for grounding. The solar cell 151a for grounding may or may not be a cell that contributes to power generation, as long as the conductive layer 160 that causes conduction between the back electrode 170a and the conductive substrate 100 to electrically connect these to each other is formed.

Moreover, though not shown in FIG. 2, a buffer layer may be formed on the photoelectric conversion layer 170b in the solar cell 151 and the solar cell 151a for grounding, and the back electrode 170a, the photoelectric conversion layer 170b, the buffer layer, and the transparent electrode 170c may be laminated in this order.

In the plural solar cells 151, in order that the back electrode 170a may be disposed in the most area of the solar cell 151 (left side in the drawing) from the area of the adjacent (immediate left in the drawing) solar cell 151 or the end (a part of the right side in the drawing) of the solar cell 151a for grounding, the back electrode 170a is formed on the surface of the nonconductive layer 130 with a predetermined interval which is a groove 180a of P1 scribing from the back electrode 170a of the adjacent solar cell 151. Even in the solar cell 151a for grounding, just like the solar cell 151, in order that the back electrode 170a may be disposed in the most area of the solar cell 151a for grounding (left side in the drawing) from the area of the end (a part of the right side in the drawing) of the adjacent (immediate left in the drawing) solar cell 151, the back electrode 170a is formed on the surface of the conductive layer 160 and the nonconductive layer 130 with a predetermined interval which is the groove 180a from the back electrode 170a of the adjacent solar cell 151. The most part of the back electrode 170a of the solar cell 151a for grounding is disposed on the conductive layer 160.

In the plural solar cells 151 and the solar cells 151a for grounding, the photoelectric conversion layers 170b are formed on the back electrodes 170a so as to fill up the grooves 180a between the adjacent back electrodes 170a. Accordingly, in the portion of the groove 180a, the photoelectric conversion layer 170b comes into direct contact with the nonconductive layer 130 and/or the conductive layer 160.

In addition, in the photoelectric conversion layer 170b, a groove 180b of P2 scribing that reaches the back electrode 170a extending from the adjacent solar cell 151 or the solar cell 151a for grounding is formed. Accordingly, the groove 180b is formed in a position (right side in the drawing) different from that of the groove 180a between the back electrodes 170a adjacent to each other.

Moreover, the transparent electrode 170c is formed on the surface of the photoelectric conversion layer 170b so as to fill up the groove 180b of the photoelectric conversion layer 170b. Therefore, in the portion of the groove 180b, the transparent electrode 170c comes into direct contact with and is electrically connected to the back electrode 170a of the adjacent solar cell 151 or the solar cell 151a for grounding. In this manner, series connection is formed between two adjacent solar cells 151 and between the solar cell 151a for grounding and the solar cell 151 adjacent thereto.

Further, in the plural solar cells 151 and the solar cells 151a for grounding, grooves 180c of P3 scribing that reach the back electrodes 170a are formed between the transparent electrodes 170c as well as the photoelectric conversion layers 170b of the solar cells 151 or the solar cell 151a for grounding and the transparent electrodes 170c as well as the photoelectric conversion layers 170b of the adjacent solar cells 151 or the solar cell 151a for grounding. By the groove 180c, two adjacent solar cells 151 are separated from each other, and the solar cell 151 and the adjacent solar cell 151a for grounding are separated from each other.

As described above, the plural solar cells 151 and the solar cells 151a for grounding are connected in series since the transparent electrode 170c of the solar cell 151 or the solar cell 151a for grounding is connected to the back electrode 170a of the adjacent solar cell 151 or the solar cell 151a for grounding.

In the photoelectric conversion device 201 of the present embodiment shown in FIG. 2, the back electrode 170a of the solar cell 151 at either end is led out as a positive terminal (+ terminal) by a lead wire such as a copper ribbon not shown in the drawing, the transparent electrode 170c of the solar cell 151 at the dead center or at the approximate center is led out as a negative terminal (− terminal) by the same lead wire, and the back electrode 170a of the solar cell 151a for grounding at either end is grounded by being electrically connected to the conductive substrate 100 that is grounded through the solar cell 151a for grounding. The conductive substrate 100 is connected to a grounding terminal by the same lead wire.

The solar cell 151 and the solar cell 151a for grounding each have a shape of a strip form that is formed in a shape of a line extending in parallel with one side of the rectangular conductive substrate 100 in a direction perpendicular to the cross-section shown in FIG. 2 (direction orthogonal to the plane of paper of FIG. 2). Accordingly, both the back electrode 170a and the transparent electrode 170c are also electrodes each having a shape of a strip form that is in parallel with a side of the conductive substrate 100 and is elongated in one direction.

The solar cell 151 of the present embodiment is called an integrated type CIGS-based solar cell (CIGS-based photoelectric conversion element), and in which the back electrode 170a is constituted with a molybdenum electrode, the photoelectric conversion layer 170b is constituted with CIGS, and the transparent electrode 170c is constituted with ZnO, for example. When a buffer layer is formed, the layer is constituted with CdS. The solar cell 151a for grounding is also constituted in the same manner.

The solar cell 151 and the solar cell 151a for grounding can be produced by, for example, a known method for producing a CIGS-based solar cell. Moreover, the groove portion having a line shape, such as the groove 180a between back electrodes 170a, the groove 180b that is formed in the photoelectric conversion layer 170b and reaches the back electrode 170a, and the groove 180c that is for separating the photoelectric conversion layer 170b together with the transparent electrode from the adjacent photoelectric conversion layer 170b and transparent electrode and reaches the back electrode 170a, can be formed by laser scribing or mechanical scribing.

In the photoelectric conversion device 201 of the present embodiment, when light enters the solar cell 151 and the solar cell 151a for grounding from transparent electrode 170c side, the light passes through the transparent electrode 170c and the buffer layer (not shown in the drawing) and reaches the photoelectric conversion layer 170b. As a result, an electromotive force is generated, and for example, a current from the transparent electrode 170c to the back electrode 170a is generated. The arrow shown in FIG. 2 indicates the direction of the current, and the movement direction of electrons is opposite to the direction of the current. Accordingly, in FIG. 2, the back electrode 170a of the solar cell 151 at the left end becomes a positive electrode (+ electrode), and the transparent electrode 170c of the solar cell 151 at the right end becomes a negative electrode (− electrode).

Next, the respective elements of the solar cell 151 and the solar cell 151a for grounding constituting the power-generating layer 140 will be described.

In the solar cell 151 and the solar cell 151a for grounding, both the back electrode 170a and transparent electrode 170c are for taking out the current generated in the photoelectric conversion layer 170b. Both the back electrode 170a and transparent electrode 170c are made of a conductive material. The transparent electrode 170c at the light entrance side needs to have translucency.

The back electrode 170a is constituted with, for example, Mo, Cr, or W, and a combination of these. The back electrode 170a may have a single-layered structure or a laminated structure such as a double-layered structure.

The thickness of the back electrode 170a is preferably 100 nm or larger, and more preferably 0.45 μm to 1.0 μm.

The method for forming the back electrode 170a is not particularly limited, and it can be formed by vapor-phase film formation method such as an electron beam vapor deposition process or a sputtering process.

The transparent electrode 170c is constituted with, for example, ZnO, indium tin oxide (ITO), or SnO₂, and a combination of these. The transparent electrode 170c may have a single-layered structure or a laminated structure such as a double-layered structure.

Moreover, the thickness of the transparent electrode 170c is not particularly limited, and is preferably 0.3 μm to 1 μm.

The method for forming the transparent electrode 170c is not particularly limited, and it can be formed by vapor-phase film formation method such as an electron beam vapor deposition method or a sputtering method. Further, an antireflection film such as MgF₂ may be formed on the transparent electrode 170c.

The buffer layer is formed for protecting the photoelectric conversion layer 170b during the formation of the transparent electrode 170c and causing the light entering the transparent electrode 170c to be transmitted to the photoelectric conversion layer 170b.

The buffer layer is constituted with, for example, CdS, ZnS, ZnO, ZnMgO, or ZnS (OHO), and a combination of these.

The thickness of the buffer layer is preferably 0.03 μm to 0.1 μm. Moreover, the buffer layer is formed by, for example, a chemical bath deposition (CBD) method, a solution growth method, and the like.

In addition, between the buffer layer such as CBD-CdS and the transparent electrode 170c such as ZnO:Al, a high resistance film made of ZnO and the like may be formed.

The photoelectric conversion layer 170b is a layer generating a current by absorbing the light that passes through the transparent electrode 170c and the buffer layer and reaches the photoelectric conversion layer 170b. In the present embodiment, the constitution of the photoelectric conversion layer 170b is not particularly limited, and for example, this layer is preferably at least one kind of compound semiconductor having a chalcopyrite structure. Moreover, the photoelectric conversion layer 170b may be at least one kind of compound semiconductor formed of an element of group Ib, an element of group IIIb, and an element of group VIb.

In addition, the photoelectric conversion layer 170b is preferably at least one kind of compound semiconductor formed of at least one kind of element of group Ib that is selected from Cu and Ag, at least one kind of element of group IIIb that is selected from Al, Ga, and In, and at least one kind of element of group VIb that is selected from S, Se, and Te, since optical absorption coefficient is further increased, and a high photoelectric conversion efficiency is obtained. Examples of such a compound semiconductor include CuAlS₂, CuGaS₂, CuInS₂, CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu (In₁₋ₓAlₓ) Se₂, Cu (In₁₋ₓGaₓ) (S,Se)₂, Ag(In₁₋ₓGaₓ)Se₂, Ag(In₁₋ₓGaₓ)(S,Se)₂, and the like.

The photoelectric conversion layer 170b particularly preferably contains CuInSe₂ (CIS) and/or Cu(In,Ga)Se₂ (CIGS) which is a solid solution of CIS containing Ga. CIS and CIGS are semiconductors having a chalcopyrite structure and reported to have a high optical absorption coefficient and a high photoelectric conversion efficiency. Furthermore, CIS and CIGS deteriorate less in terms of the efficiency even being irradiated with light and the like and have excellent durability.

The photoelectric conversion layer 170b contains impurities for obtaining a desired conductivity type of a semiconductor. The impurities can be added to the photoelectric conversion layer 170b by diffusing them from the adjacent layer and/or by active doping. In the photoelectric conversion layer 170b, constituent elements of the group semiconductor and/or the impurities may exhibit concentration distribution, and plural areas of layers having different semiconduction such as an n-type, a p-type, and an i-type may be included in the photoelectric conversion layer 170b.

For example, in the CIGS-based semiconductor, if the Ga content in the photoelectric conversion layer 170b is allowed to have distribution in the thickness direction, it is possible to control the width of band gap/mobility of carriers and the like, and the semiconductor can be designed to have a high photoelectric conversion efficiency.

The photoelectric conversion layer 170b may contain one, two, or more kinds of semiconductors other than the group I-III-VI semiconductor. Examples of the semiconductors other than the group semiconductor include semiconductors formed of elements of group IVb, such as Si (group IV semiconductors); semiconductors formed of elements of group IIIb and group Vb, such as GaAs (group III-V semiconductors); semiconductors formed of elements of group IIb and group VIb, such as CdTe (group II-VI semiconductors); and the like. The photoelectric conversion layer 170b may contain optional components other than the semiconductor and the impurities for obtaining a desired conductivity type, as long as the characteristics are not impaired.

Furthermore, the content of the group semiconductor in the photoelectric conversion layer 170b is not particularly limited. The content of the group semiconductor in the photoelectric conversion layer 170b is preferably 75% by mass or more, more preferably 95% by mass or more, and particularly preferably 99% by mass or more.

In the present embodiment, when a CIGS layer is used as the photoelectric conversion layer 170b, as the method for forming the CIGS layer, 1) a multi-source simultaneous vapor deposition process, 2) selenization process (selenization/sulfurization process), 3) a sputtering process, 4) a hybrid sputtering process, 5) a mechanochemical process, and the like are known.

As the 1) multi-source simultaneous vapor deposition process, a 3-step process (J. R. Tuttle et al., Mat. Res. Soc. Symp. Proc., Vol. 426 (1996), p. 143, and the like) and a simultaneous vapor deposition process of EC group (L. Stolt et al.: Proc. 13^{th} ECPVSEC (1995, Nice), 1451, and the like) are known.

The 3-step process is a method in which In, Ga, and Se are simultaneously vapor-deposited first in a high degree of vacuum at a substrate temperature of 300° C., Cu and Se are then simultaneously vapor-deposited by increasing the temperature to 500° C. to 560° C., and then In, Ga, and Se are simultaneously vapor-deposited again.

The simultaneous vapor deposition process of EC group is a method in which CIGS containing an excess amount of Cu is vapor-deposited first, and then CIGS containing an excess amount of In is vapor-deposited later.

As methods that are obtained by ameliorating the above methods to improve crystallinity of the CIGS film, a) a method of using ionized Ga (H. Miyazaki, et al., phys. stat. sol. A, vol. 203 (2006), p. 2603, and the like), b) a method of using cracked Se (the 68^{th} academic lecture of the Japan Society of Applied Physics, lecture proceeding (2007′ autumn, Hokkaido Institute of Technology) 7P-L-6 and the like), c) a method of using radicalized Se (the 54^{th} academic lecture of the Japan Society of Applied Physics, lecture proceeding (2007′ spring, Aoyama Gakuin University) 29P-ZW-10 and the like), d) a method of using a photo-excitation process (the 54^{th} academic lecture of the Japan Society of Applied Physics, lecture proceeding (2007′ spring, Aoyama Gakuin University) 29P-ZW-14 and the like), and the like are known.

The 2) selenization process is also called a 2-step process and is a method in which a metal precursor of laminated film such as a Cu layer/an In layer or a (Cu—Ga) layer/an In layer is first formed into a film by a sputtering process, a vapor deposition process, an electrodeposition process, or the like, and the film is heated at about 450° C. to 550° C. in selenium vapor or hydrogen selenide to produce a selenium compound such as Cu(In₁₋ₓGaₓ)Se₂ by a thermal diffusion reaction. This method is called a vapor-phase selenization process. In addition, there is a solid-phase selenization process in which solid-phase selenium is deposited onto a metal precursor film, and a solid-phase diffusion reaction is caused using the solid-phase selenium as a selenium source to conduct selenization.

Regarding the selenization process, as a method for avoiding sudden volume expansion caused at the time of selenization, a method of mixing in advance selenium in a certain proportion with a metal precursor film (T. Nakada et al., Solar Energy Materials and Solar Cells 35 (1994), 204-214, and the like) and a method of forming a multilayered precursor film by interposing selenium between thin metal layers (for example, performing laminating in the manner such as a Cu layer/an In layer/a Se layer . . . a Cu layer/an In layer/a Se layer) (T. Nakada et al., Proc. of 10^{th} European Photovoltaic Solar Energy Conference (1991), 887-890, and the like) are known.

Furthermore, as a method for forming a graded band gap CIGS film, there is a method of depositing a Cu—Ga alloy film first, depositing an In film onto the alloy film, and causing the Ga concentration to have gradient in the film thickness direction by using natural thermal diffusion during selenization (K. Kushiya et al., Tech. Digest 9^{th} Photovoltaic Science and Engineering Conf. Miyazaki, 1996 (Intn. PVSEC-9, Tokyo, 1996), p. 149, and the like).

As the 3) sputtering process, a process of using polycrystalline CuInSe₂ as a target, a binary sputtering process that uses Cu₂Se and In₂Se₃ as targets and mixed gas of H₂Se/Ar as sputtering gas (J. H. Ermer, et al., Proc. 18^{th} IEEE Photovoltaic Specialists Conf. (1985), 1655-1658, and the like), and a ternary sputtering process in which a Cu target, an In target, and a Se or CuSe target are subjected to sputtering in Ar gas (T. Nakada, et al., Jpn. J. Appl. Phys. 32 (1993), L1169-L1172, and the like) are known.

As the 4) hybrid sputtering process, a hybrid sputtering process in which metals of Cu and In are subjected to DC sputtering, and only Se is vapor-deposited in the sputtering process described above (T. Nakada, et al., Jpn. Appl. Phys. 34 (1995), 4715-4721, and the like) is known.

The 5) mechanochemical process is a method in which raw materials according to the composition of CIGS are put into a vessel of a planetary ball mill to obtain CIGS powder by mixing the raw materials with each other by mechanical energy, the powder is then coated onto a substrate by screen printing, and the resultant is annealed to obtain a CIGS film (T. Wada et al., Phys. stat. sol. A, Vol. 203 (2006), p. 2593, and the like).

Examples of other CIGS film formation processes include a screen printing process, a close-spaced sublimation process, an MOCVD process, a spraying process, and the like. For example, in the screen printing process or the spraying process, a fine particle film containing elements of groups Ib, IIIb, and VIb is formed on a substrate, and the resultant is subjected to pyrolysis treatment (at this time, the pyrolysis treatment may be conducted in an atmosphere of an element of group VIb), whereby crystals having a desired composition can be obtained (JP 9-74065 A, JP 9-74213 A, and the like).

The solar cell 151 and the solar cell 151a for grounding of the photoelectric conversion device 201 (solar cell module) as the first embodiment described above are integrated type CIGS-based solar cells. However, the present invention is not limited thereto and they may be solar cells functioning as the solar cell of the photoelectric conversion device (solar cell module) and the photoelectric conversion element of the present invention. Particularly, the constitution of the photoelectric conversion layer thereof may be, for example, an amorphous silicon (a-Si)-based solar cell, a tandem structure-based solar cell (a-Si/a-SiGe tandem structure solar cell), a Series-Connection through Apertures formed on Film (SCAF) structure-based solar cell (a-Si series connection structure solar cell), a Cadmium/Telluride (CdTe)-based solar cell, a group III-V semiconductor-based solar cell, a thin silicon film-based solar cell, a dye-sensitized solar cell, or an organic solar cell, and may be a solar cell called substrate type or super straight type.

Moreover, in the photoelectric conversion device 201 of the embodiment shown in FIG. 2, the back electrode 170a side is a positive electrode (+ electrode), and the transparent electrode 170c side is a negative electrode (− electrode). However, the present invention is not limited thereto, and according to the type of the solar cell, the back electrode 170a side may be a negative electrode (− electrode), and the transparent electrode 170c side may be a positive electrode (+ electrode).

For example, when a tandem structure-based solar cell (a-Si/a-SiGe tandem structure solar cell) is used as the solar cell 151 and the solar cell 151a for grounding, as the back electrode 170a, an electrode as a laminate of silver (Ag) and ZnO can be used for example, ITO can be used as the transparent electrode 170c, and as the photoelectric conversion layer 170b, for example, it is possible to use a photoelectric conversion layer that is obtained by laminating an n-type semiconductor layer, an intrinsic semiconductor layer such as fine crystalline silicon and amorphous silicon germanium (a-SiGe), and a p-type semiconductor layer on each other and further laminating an n-type semiconductor layer, an intrinsic semiconductor layer such as amorphous silicon (a-Si), and a p-type semiconductor layer on the above resultant.

Further, when a CdTe-based solar cell is used as the solar cell 151 and the solar cell 151a for grounding, as the photoelectric conversion layer 170b, for example, a photoelectric conversion layer called a Cadmium/Telluride (CdTe) type can be used.

Next, the conductive layer 160 of the solar cell 151a for grounding will be described.

The conductive layer 160 is a portion that is the greatest feature of the present invention. In the solar cell 151a for grounding, this layer is disposed between the conductive substrate 100 and the back electrode 170a instead of the nonconductive layer 130 and has conductivity. The conductive layer 160 is for electrically connecting the back electrode 170a to the grounded conductive substrate 100 and causing conduction therebetween, and for grounding the back electrode 170a.

The conductive layer 160 is in a state in which the component of the conductive substrate 100, the component of the nonconductive layer 130, and the component of the back electrode 170a are mixed together, and as a result, this layer obtains conductivity.

Herein, in the example shown in FIG. 2, the conductive layer 160 is formed only in the portion under the back electrode 170a of the solar cell 151a for grounding. In the portion under the groove 180a, the conductive layer 160 is not formed, and only the nonconductive layer 130 remains. However, the present invention is not limited to this, and within the solar cell 151a for grounding, the conductive layer 160 may also be formed in the portion under the groove 180a and in the portion under the back electrode 170a of the adjacent solar cell 151. However, in this case, since a short circuit is caused between the back electrode 170a of the solar cell 151a for grounding and the back electrode 170a of the adjacent solar cell 151, the solar cell 151a for grounding does not contribute to power generation.

The conductive layer 160 can be formed as shown in FIG. 4 by the following manner. That is, an ultrasonic solder 190 is coated onto the transparent electrode 170c of the solar cell 151 which is to be the solar cell 151a for grounding, and only the solar cell 151a on which the ultrasonic solder 190 has been coated is subjected to heating and ultrasonic treatment to break the nonconductive layer 130 that corresponds to the portion of the solar cell 151a that has been coated with the ultrasonic solder 190. By the above treatment, the surfaces of the conductive substrate 100 and the back electrode 170a that come into contact with the broken nonconductive layer 130 are also dissolved and mixed with each other to create a mixed state where the conductive substrate 100, the back electrode 170a, and the broken nonconductive layer 130 are mixed together. Thus, the conductive layer 160 is formed. It is clarified how the mixed state of the conductive layer 160 is formed. However, for example, presumably, when only the solar cell 151a coated with the ultrasonic solder 190 is subjected to the heating and ultrasonic treatment, the nonconductive layer 130 corresponding to the portion of the solar cell 151a that has been coated with the ultrasonic solder 190 may be broken and become porous by forming fine pores, and when the surfaces of the conductive substrate 100 and the back electrode 170a that have come into contact with the broken nonconductive layer 130 are dissolved, the dissolved resultant may permeate the fine pores of the broken nonconductive layer 130, whereby the mixed state may be formed. In addition, when the transparent electrode 170c and the photoelectric conversion layer 170b of the solar cell 151a for grounding are also broken, the conductive layer 160 into which the broken resultant as well as the ultrasonic solder 190 are mixed may be formed.

The solder may be coated onto the entire surface of the solar cell 151a for grounding, but as shown in FIG. 4, a part of the transparent electrode 170c may be left as is.

Soldering may be performed sequentially in the shape of a line while supplying the solder on a cell without performing coating of the solder. However, in view of production, a method of disposing solder in the shape of a line and then performing soldering on the line at a time or a method of performing soldering on plural linear sites simultaneously is preferable.

The conductivity of the conductive layer 160 formed in the above manner is considered to be determined depending on the mixed state of the conductive layer 160. Therefore, according to the constitution or function of the solar cell 151 which is to be the solar cell 151a for grounding, and whether or not the power-generating function is required, particularly, according to the thickness of the nonconductive layer 130 and the like, the mixed state can be controlled by appropriately controlling the amount of the ultrasonic solder 190 used for coating, the conditions in the heating and ultrasonic treatment such as the heating temperature, the heating time, the intensity of the ultrasonic waves and the time of ultrasonic treatment, and the like, whereby necessary conductivity can be obtained.

The relationship between the conductivity of the conductive layer 160; the constitution as well as the function of the solar cell 151, particularly, the thickness of the nonconductive layer 130 and the like; and the amount of the ultrasonic solder 190 used for coating, the conditions in the heating and ultrasonic treatment such as the heating temperature, the heating time, the intensity of the ultrasonic waves and the time of the ultrasonic treatment, and the like may be determined in advance by experiments, simulation, and the like.

In the present embodiment, the conductive layer 160 is formed in the manner described above, but the present invention is not limited thereto. As long as the nonconductive layer 130 is formed on the substrate made of a conductive material, the conductive layer 160 may be formed in any stage during the production of the photoelectric conversion device.

For example, a portion of the nonconductive layer 130 on the conductive substrate 100 that is to be the solar cell 151a for grounding may be coated with the ultrasonic solder and subjected to heating and ultrasonic treatment, such that the conductive layer 160 as a mixture of the broken nonconductive layer 130, the conductive substrate 100, and the ultrasonic solder is formed, and then the plural solar cells 151 and the solar cells 151a for grounding may be formed. Moreover, the back electrode 170a may be formed on the nonconductive layer 130 on the conductive substrate 100, the back electrode 170a in a portion to be the solar cell 151a for grounding may be coated with the ultrasonic solder and subjected to heating and ultrasonic treatment, such that the conductive layer 160 as a mixture of the broken nonconductive layer 130, the conductive substrate 100, and the back electrode 170a is formed, or the conductive layer 160 as the mixture further containing the ultrasonic solder is formed. Thereafter, the photoelectric conversion layer 170b and the transparent electrode 170c may be formed in this order on the conductive layer 160 to form plural solar cells 151 and solar cells 151a for grounding. In addition, after the photoelectric conversion layer 170b is formed, the conductive layer 160 may be formed in the same manner as above, and the transparent electrode 170c may be formed thereon to form plural solar cells 151 and solar cells 151a for grounding.

In any of these methods, the solar cell 151 is completed after the conductive layer 160 is formed, and subsequently one or more of the back electrode 170a, the photoelectric conversion layer 170b, and the transparent electrode 170c need to be formed, so accurate alignment is required. Therefore, it is preferable to form the conductive layer 160 after the solar cell 151 is formed.

The photoelectric conversion device 201 as the first embodiment of the present invention is basically constituted as above, and produced in the following manner.

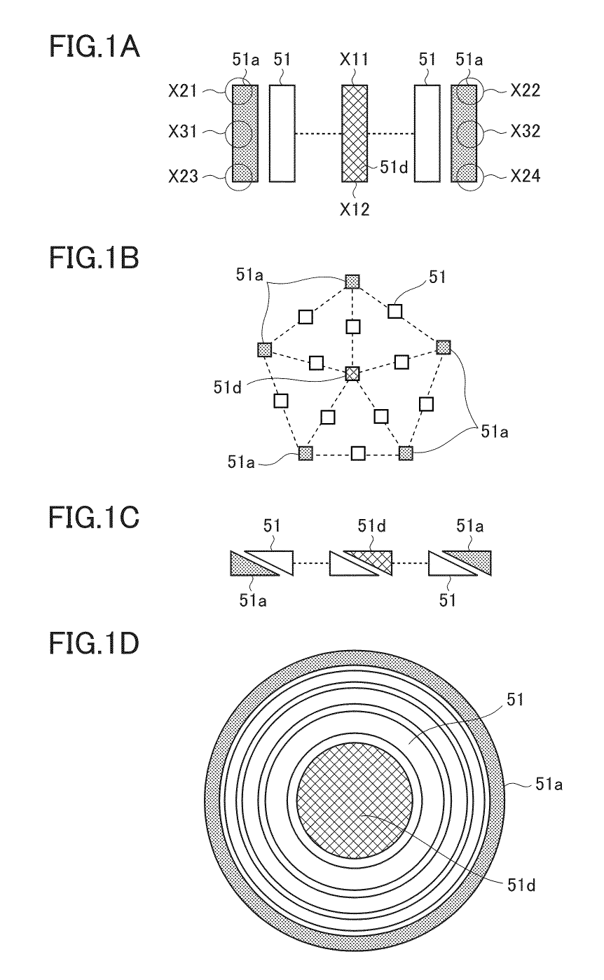

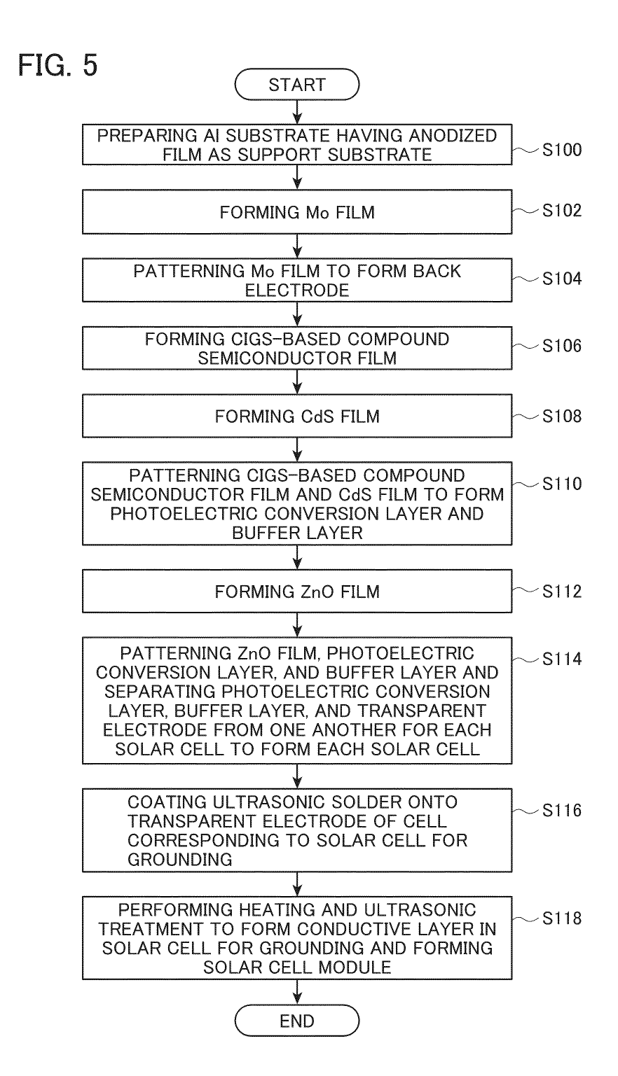

FIG. 5 is a flow chart illustrating an example of a method for producing the photoelectric conversion device as the first embodiment of the present invention shown in FIG. 1.

As shown in FIG. 5, by using an Al substrate as the conductive substrate 100, anodization treatment is performed by the method described above to form an anodized film to be the nonconductive layer 130 on the substrate surface. In this manner, an Al substrate having the anodized film is formed and prepared as the support substrate 110 (Step S100).

Needless to say, an Al substrate having an anodized film may be prepared in advance as the support substrate 110.

Thereafter, on the nonconductive layer 130 of the support substrate 110, Mo is deposited by a known film formation method such as DC magnetron sputtering process and the like described above, thereby forming a Mo film (Step S102).

Next, the Mo film formed on the nonconductive layer 130 in this manner is cut by the laser scribing process described above and patterned to a pattern 1 to form the groove 180a, thereby forming the back electrode 170a (Step S104).

Subsequently, on the back electrode 170a formed on the nonconductive layer 130, a CIGS-based compound semiconductor film (p-type CIGS-based light-absorbing film) which is to be the photoelectric conversion layer 170b is formed by a known method such as a selenization/sulfurization process or a multi-source simultaneous vapor deposition process described above so as to fill up the groove 180a (Step S106).

Then on the CIGS-based compound semiconductor film formed in this manner, a CdS film (n-type high-resistance buffer layer) which is to be a buffer layer is formed by a known method such as CBD method described above (Step S108).

Thereafter, the CIGS-based compound semiconductor film and the CdS film formed on the back electrode 170a in this manner are together cut by the mechanical scribing process described above and patterned to a pattern 2 to form the groove 180b reaching the back electrode 170a, thereby forming the photoelectric conversion layer 170b and the buffer layer (Step S110).

Subsequently, on the buffer layer (photoelectric conversion layer 170b) formed in this manner, a ZnO film (n-type transparent conductive ZnO film as a window layer) which is to be the transparent electrode 170c is formed by a known method such as the MOCVD process or the RF sputtering process described above so as to fill up the groove 180b (Step S112).

Next, the ZnO film, the buffer layer, and the photoelectric conversion layer 170b formed in this manner are together cut by the mechanical scribing process described above and patterned to a pattern 3 to form the groove 180c reaching the back electrode 170a between adjacent solar cells 151 and to separate the photoelectric conversion layer 170b, the buffer layer, and the transparent electrode 170c from one another for each solar cell 151, thereby forming plural solar cells 151 (Step S114).

Thereafter, the ultrasonic solder 190 is coated onto the transparent electrode 170c of the solar cell 151 that is predetermined to become the solar cell 151a for grounding (Step S116).

Then heating and ultrasonic treatment is selectively performed on the transparent electrode 170c of the solar cell 151 coated with the ultrasonic solder 190. In this manner, the nonconductive layer 130 is broken such that the component thereof is mixed with the component of the conductive substrate 100 and the component of the back electrode 170a, thereby forming the conductive layer 160 (Step S118).

In the above manner, the photoelectric conversion device 201 of the present embodiment is formed (Step S118).

Next, the photoelectric conversion device as the second embodiment of the present invention will be described.

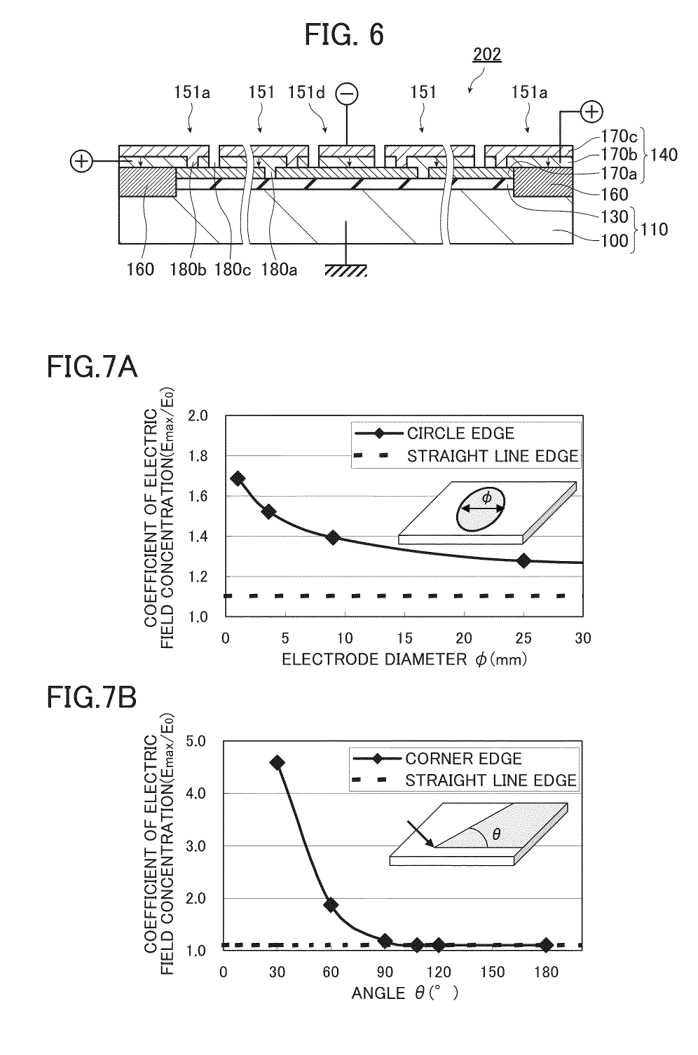

FIG. 6 is a schematic cross-sectional view of a photoelectric conversion device 202 (solar cell module) as the second embodiment of the semiconductor device of the present invention.

The photoelectric conversion device 202 of the present embodiment shown in FIG. 6 is constituted in the same manner as the photoelectric conversion device 201 as the first embodiment shown in FIG. 2, except that the constitution of the conductive layer 160 of the solar cell 151a for grounding is different. Therefore, the same constituent elements are marked with the same reference symbols, and the detailed description thereof will not be repeated.

As shown in FIG. 6, in the photoelectric conversion device 202 of the present embodiment, instead of the conductive layer 160 of the solar cell 151a for grounding of the photoelectric conversion device 201 of the first embodiment, the conductive layer 160 is formed in a manner in which the back electrode 170a extending from the adjacent solar cell 151 is directly disposed between the conductive substrate 100 and the photoelectric conversion layer 170b.

Accordingly, in the photoelectric conversion device 202 of the present embodiment, the back electrode 170a comes into direct contact with and is electrically conducted with the conductive substrate 100 grounded. Therefore, the back electrode 170a of the solar cell 151a for grounding can be grounded through the conductive substrate 100.

Consequently, needless to say, in the photoelectric conversion device 202 of the present embodiment, the constitution of the solar cell 151 and the solar cell 151a for grounding may be in any form of solar cell (a photoelectric conversion element or a photoelectric conversion layer), just like the photoelectric conversion device 201 as the first embodiment described above.

In the photoelectric conversion device 202, the plural solar cells 151 and the solar cells 151a for grounding can be formed by using the support substrate 110 including the conductive substrate 100 such as an Al substrate in which the nonconductive layer 130 such as an anodized film is not formed only in the portion corresponding to the solar cells 151a for grounding while the nonconductive layer 130 such as an anodized film is formed in the other portion, and by forming the power-generating layer 140 just like the case of the photoelectric conversion device 201 as the first embodiment described above, that is, by forming the back electrode 170a and the conductive layer 160, the photoelectric conversion layer 170b and the buffer layer, and the transparent electrode 170c in this order. The photoelectric conversion device 202 of the present embodiment can be formed in this manner.

Instead of the support substrate 110 including the conductive substrate 100 in which the nonconductive layer 130 is formed only in the portion corresponding to the solar cells 151a for grounding, the support substrate 110, in which the nonconductive layer 130 such as an anodized film in the portion corresponding to the solar cells 151a for grounding of the support substrate 110 where the nonconductive layer 130 is formed on the entire surface of the conductive substrate 100 just like an anodized Al substrate has been removed by scribing or etching, may be used for formation of the power-generating layer 140 starting from vapor deposition of the back electrode 170a. The photoelectric conversion device 202 of the present embodiment may also be formed in this manner.

Any of the photoelectric conversion device 201 (solar cell module) as the first embodiment and the photoelectric conversion device 202 (solar cell module) as the second embodiment may be provided with a conductive frame. This conductive frame refers to a member for a solar cell module that is mounted on circumferential edge portions, that is, edge portions of ridge side, eaves side, left side, and right side of a solar cell module for placing the solar cell module on a roof underlayment material such as sheathing roof board or water-proofing under roofing material. As the conductive frame, aluminum having suitable workability and environmental resistance is mainly used.

In addition, in any of the photoelectric conversion device 201 (solar cell module) as the first embodiment and the photoelectric conversion device 202 (solar cell module) as the second embodiment, a solar cell string may be formed by connecting the devices in series. Moreover, a solar cell array may be formed by connecting the solar cell strings to each other in parallel.

Hereinafter, the photoelectric conversion device 201 as the first embodiment, the photoelectric conversion device 202 as the second embodiment, the conventional photoelectric conversion device 203, and a solar cell module 50 that is described as a general photoelectric conversion device in FIG. 7 of JP 4612731 B will be compared to one another.

In each of the photoelectric conversion device 201 as the first embodiment, the photoelectric conversion device 202 as the second embodiment, the conventional photoelectric conversion device 203, and a solar cell module 50 that is described as a general photoelectric conversion device in FIG. 7 of JP 4612731 B, for example, 307 solar cells 151 having a short side of 5 mm and a long side of 1,000 mm are arranged, whereby a photoelectric conversion device that can produce an output of 100 W can be obtained respectively. The following Table 1 shows potential differences VX11, VX12, VX21, VX22, VX23, VX24, VX31, and VX32 obtained at this time between the solar cell and the conductive substrate at each point of end portions X11 and X12 of the one at the center among plural solar cells, end portions X21, X22, X23, and X24 of two solar cells at both ends of plural solar cells, and central portions X31 and X32 of two solar cells at both ends of plural solar cells in each power-generating layer 140 of the photoelectric conversion device 201 as the first embodiment, the photoelectric conversion device 202 as the second embodiment, the conventional photoelectric conversion device 203, and a solar cell module 50 that is described as a general photoelectric conversion device in FIG. 7 of JP 4612731 B.

TABLE 1

| | Photoelectric | Photoelectric | |
|---|---|---|---|
| | conversion devices | conversion device | Solar cell module |
| | 201 and 202 | 203 | 50 |
| VX11 | 76.5 V | 0 V | 76.5 V |
| VX12 | 76.5 V | 0 V | 76.5 V |
| VX21 | 0 V | 76.5 V | 0 V |
| VX22 | 0 V | 76.5 V | 153 V |
| VX23 | 0 V | 76.5 V | 0 V |
| VX24 | 0 V | 76.5 V | 153 V |
| VX31 | 0 V | 76.5 V | 0 V |
| VX32 | 0 V | 76.5 V | 153 V |

From the above Table 1, it is understood that the potential difference between each solar cell and the conductive substrate is reduced in the photoelectric conversion device 201 and 202 even at the same output. Accordingly, since a withstand voltage VW required between the power-generating layer and the conductive substrate can be reduced, excellent withstand voltage properties in insulation can be obtained.

In the manner described above, in the photoelectric conversion device 201 as the first embodiment and the photoelectric conversion device 202 as the second embodiment of the present invention, the solar cells 151a for grounding are disposed in the vicinity of both ends of the power-generating layer 140, and the remaining solar cells 151 are disposed in a straight line while being adjacent to the solar cell 151a for grounding, and two serially connected arrays are connected to each other in parallel. As a result, among all of the solar cells 151, the solar cell 151d becomes the solar cell 151 that exhibits the largest potential difference V1d with respect to the conductive substrate 100. Accordingly, since the withstand voltage VW is reduced, the insulating properties are improved, and excellent withstand voltage properties in insulation are obtained.

The present invention is basically constituted as above. So far, photoelectric conversion devices have been described in detail as examples of the semiconductor device of the present invention. However, the present invention is not limited to the above embodiments, and needless to say, within a range that does not depart from the gist of the present invention, various types of improvement or modification can be made.

What is claimed is:

1. A semiconductor device comprising:
a conductive substrate made of a conductive material;
a nonconductive layer that is disposed in at least a portion of the surface of the conductive substrate;
plural semiconductor elements that are arranged on the nonconductive layer;
a wiring that electrically connects the plural semiconductor elements to one another; and
at least one electrical connection portion that connects the conductive substrate to the semiconductor elements or the wiring,
wherein the semiconductor element that shows a largest potential difference with respect to the conductive substrate is arranged in a position excluding a geometric end of an array composed of the plural semiconductor elements.

2. The semiconductor device according to claim 1,
wherein the at least one electrical connection portion comes into contact with at least one semiconductor element positioned within a range that includes 10% of a number of the plural semiconductor elements from at least one end of the array, and
when the electrical connection portion comes into contact with plural semiconductor elements, the semiconductors are equipotential to each other.

3. The semiconductor device according to claim 1,
wherein the at least one electrical connection portion comes into contact with at least one semiconductor element positioned within a range that includes 5% of a number of the plural semiconductor elements from at least one end of the array, and
when the electrical connection portion comes into contact with plural semiconductor elements, the semiconductors are equipotential to each other.

4. The semiconductor device according to claim 1,
wherein the at least one electrical connection portion comes into contact with a semiconductor element positioned in at least one end of the array, and
when the electrical connection portion comes into contact with plural semiconductor elements, the semiconductor elements are equipotential to each other.

5. The semiconductor device according to claim 1,
wherein the nonconductive layer is formed by subjecting the conductive substrate to anodization treatment, and
among the plural semiconductor elements, at least one semiconductor element showing a largest potential difference comes into contact with the electrical connection portion.

6. The semiconductor device according to claim 1,
wherein the plural semiconductor elements are arranged in a form of a concentric circle, and
at least one semiconductor element showing a largest potential difference with respect to the conductive substrate is disposed at a center of a concentric circle-like arrangement.

7. The semiconductor device according to claim 1,
wherein the plural semiconductor elements are arranged in a straight line, and
two serially-connected arrays of the semiconductor elements are connected to each other in parallel.

8. The semiconductor device according to claim 5,
wherein the conductive substrate is a substrate made of aluminum.

9. The semiconductor device according to claim 5,
wherein the conductive substrate is a composite aluminum substrate made of a composite material.

10. The semiconductor device according to claim 9,
wherein the composite aluminum substrate is a clad plate composed of a steel plate and an aluminum plate or a clad plate composed of a stainless steel plate and an aluminum plate.

11. A solar cell module comprising:
photoelectric conversion elements,
wherein the photoelectric conversion elements are the semiconductor elements according to claim 1 that function as solar cells.

12. The solar cell module according to claim 11,
wherein the solar cell is a thin-film type solar cell.

13. The solar cell module according to claim 12,
wherein the thin-film type solar cell is an integrated type thin-film solar cell.

14. The solar cell module according to claim 11,
wherein the solar cell is a thin-film type solar cell selected from among a CIS-based thin-film type solar cell, a CIGS-based thin-film type solar cell, a thin silicon film-based thin-film type solar cell, a CdTe-based thin film type solar cell, a group III-V semiconductor-based thin-film type solar cell, a dye-sensitized thin-film type solar cell, and an organic thin-film type solar cell.

15. The solar cell module according to claim 11,
wherein the solar cell includes at least one kind of compound semiconductor having a chalcopyrite structure.

16. The solar cell module according to claim 11,
wherein the solar cell includes at least one kind of compound semiconductor composed of an element of group Ib, an element of group IIIB, and an element of group VIb.

17. The solar cell module according to claim 11,
wherein the solar cell includes at least one kind of compound semiconductor composed of at least one kind of element of group Ib selected from a group consisting of Cu and Ag, at least one kind of element of group IIIb selected from a group consisting of Al, Ga, and In, and at least one kind of element of group VIb selected from a group consisting of S, Se, and Te.

18. The solar cell module according to claim 11, further comprising a conductive frame.

19. A solar cell string which is obtained by connecting a plurality of the solar cell modules according to claim 11 to each other in series.

20. A solar cell array which is obtained by connecting a plurality of the solar cell strings according to claim 19 to each other in parallel.
